(19) United States
(12) Patent Application Publication
(10) Pub. No.: US 2025/0113579 A1
(43) Pub. Date: Apr. 3, 2025

(54) SEMICONDUCTOR DEVICE

(71) Applicant: DYNAX SEMICONDUCTOR, INC., Kunshan (CN)

(72) Inventors: Naiqian ZHANG, Kunshan (CN); Yi PEI, Kunshan (CN); Linlin SUN, Kunshan (CN); Xinchuan ZHANG, Kunshan (CN)

(21) Appl. No.: 18/725,651

(22) PCT Filed: Dec. 21, 2022
(86) PCT No.: PCT/CN2022/140732

§ 371 Date: Jun. 28, 2024

(30) Foreign Application Priority Data
Dec. 31, 2021 (CN) 202111666167.8

(51) Int. Cl. H10D 64/23; H10D 30/47; H10D 64/27; H10D 84/82

(52) U.S. Cl. CPC H10D 64/254; H10D 30/475; H10D 64/411; H10D 84/82

(57) ABSTRACT

Embodiments of the present disclosure disclose a semiconductor device including a plurality of sources, a plurality of gates, and a plurality of drains located in an active area. In the active area, the sources, the gates, and the drains are alternately arranged along a first direction, and along the first direction, the sources include two sources respectively closest to ends of the arrangement, and any one of the gates is located between one of the sources and one of the drains, a length of at least a source located at the center along the first direction is greater than lengths of sources located at both ends along the first direction. The semiconductor device further includes a plurality of rows of through holes extending through a substrate and a multilayer semiconductor layer, a plurality of rows of the through holes are arranged along the first direction, and an orthographic projection.

### CROSS REFERENCE TO RELATED APPLICATIONS

This patent application is a National Stage Entry of PCT/CN2022/140732 filed on Dec. 21, 2022, which claims the benefit and priority of Chinese Patent Application No. 202111666167.8 filed on Dec. 31, 2021, the disclosures of which are incorporated by reference herein in their entirety as part of the present application.

### BACKGROUND

Embodiments of the present disclosure relate to the technical field of microelectronics, and particularly, relate to a semiconductor device.

Gallium nitride (GaN) semiconductor material has become a current research hotspot due to its characteristics such as large bandgap width, high electron saturation drift velocity, high breakdown field strength, and good thermal conductivity. In terms of electronic devices, gallium nitride material is more suitable for manufacturing high-temperature, high-frequency, high-voltage, and high-power semiconductor devices compared to silicon and gallium arsenide. Therefore, gallium nitride-based electronic devices have good application prospects, such as for the preparation of gallium nitride (GaN) high electron mobility transistor (High Electron Mobility Transistor, HEMT) devices.

GaN HEMT device is a field effect transistor that uses two materials with different energy gaps (such as AlGaN/GaN) to form a heterojunction to provide a channel for carriers. During the actual operation of GaN HEMT devices, especially when the power level is high, a large amount of heat will be generated, which will increase the junction temperature of the device. If the heat generated cannot be dissipated, the junction temperature of the device will become higher and higher, and if the maximum junction temperature that it can withstand is exceeded, the device will be burned.

In the existing technology, GaN HEMT devices are often designed into a multi-gate structure; since the heat dissipation rate in the center area of the device is lower than that in the edge area, the junction temperature in the center area is often the highest; if effective heat dissipation is not achieved, the device will be burned out in advance, and increasing the area of the heat dissipation area of the center area will affect the radio frequency characteristics of the device. Therefore, addressing how to ensure the radio frequency characteristics of the semiconductor device while enhancing the heat dissipation capability of the center area of the semiconductor device is an urgent problem to be solved.

### BRIEF DESCRIPTION

Embodiments of the present disclosure provide a semiconductor device to ensure the radio frequency characteristics of the semiconductor device while enhancing the heat dissipation capability of the center area of the semiconductor device.

A semiconductor device including an active area and a non-active area surrounding the active area;
wherein the semiconductor device further includes
a substrate;
a multilayer semiconductor layer, located on one side of the substrate;
a plurality of sources, a plurality of gates, and a plurality of drains, located on one side of the multilayer semiconductor layer away from the substrate and located in the active area, wherein, in the active area, the sources, the gates, and the drains are alternately arranged along a first direction, and along the first direction, the sources include two sources respectively closest to ends of the arrangement, and any one of the gates is located between one of the sources and one of the drains, and the first direction is parallel to a plane where the substrate is located; and
along the first direction, a length of at least a source located at the center along the first direction is greater than lengths of sources located at both ends along the first direction; and
the semiconductor device further includes a plurality of rows of through holes extending through the substrate as well as the multilayer semiconductor layer, a plurality of rows of the through holes are arranged along the first direction, and an orthographic projection of the source on the substrate overlaps with an orthographic projection of the through holes on the substrate, along the first direction, the sources located at both ends are correspondingly provided with a rows of the through holes, and at least the source located at the center is correspondingly provided with b rows of the through holes, and b=2*a is satisfied, and both a and b are positive integers, and a≥1, b≥2.

Along the first direction, an electrode located at the center of the arrangement may be a drain; and
lengths of at least the two sources closest to the drain along the first direction are greater than lengths of the sources located at both ends along the first direction, and b rows of through holes are provided correspondingly.

Along the first direction, an electrode located at the center of the arrangement may be a source; and
a length of at least the source along the first direction is greater than lengths of the sources located at both ends along the first direction, and b rows of through holes are provided correspondingly.

Number of rows of through holes provided corresponding to each source may be a or b.

Among any two of the nearest sources, number of rows of through holes corresponding to the source close to the center of the arrangement may be greater than or equal to number of rows of through holes corresponding to the sources away from the center of the arrangement.

Along the first direction, starting from a first source located at one end, the m-th source may be provided with b rows of through holes correspondingly;
a length Yₘ of the m-th source along the first direction satisfies Yₘ≥3Yₕ+2Y_{c}; and
wherein Yₕ is a length of the through hole along the first direction, Y is a distance between the opposite edges of the sources and the through hole located at both ends in the first direction, and m is a positive integer greater than 1.

A distance L between two rows of through holes corresponding to the same source in the first direction may satisfy L≥Yₕ; and
wherein Yₕ is a length of the through hole along the first direction.

A distance H between the opposite edges of the sources and the through holes between the sources located at both ends in the first direction may satisfy Y_{c}≤H≤Yₕ+Y_{c}; and
wherein Yₕ is a length of the through hole in the first direction, and Y_{c} is a distance between the opposite edges of the sources and the through holes located at both ends in the first direction.

Number of the through holes in each row of through holes may be equal.

In each row of the through holes, a line connecting the geometric centers of the through holes at the same number of position may be parallel to the first direction.

In embodiments of the present disclosure, by arranging a length of at least a source located at the center along the first direction to be greater than lengths of sources located at both ends along the first direction, the area of the source located at the center is greater than the area of the source located at both ends, thus increasing the area of the heat dissipation area of the center area of the semiconductor device, and improving the heat dissipation capacity of the center area of the semiconductor device. At the same time, by arranging the number of rows of through holes provided corresponding to at least the source located at the center to be two times the number of rows of through holes provided corresponding to the sources located at both ends, the current flow path of the central device may be similar to that of the edge device while taking into account the heat dissipation of the device, thereby improving the symmetry of the overall current flow path and ensuring the radio frequency characteristics of the semiconductor device.

### BRIEF DESCRIPTION OF THE DRAWINGS

FIG. 1 is a cross-sectional structural schematic diagram of a semiconductor device provided by an embodiment of the present disclosure;

FIG. 2 is a top structural schematic diagram of a semiconductor device provided by an embodiment of the present disclosure;

FIG. 3 is a partial top structural schematic diagram of a semiconductor device provided by an embodiment of the present disclosure; and

FIG. 4 is a partial top structural schematic diagram of another semiconductor device provided by an embodiment of the present disclosure.

### DETAILED DESCRIPTION

The present disclosure will be further described in detail below in conjunction with the drawings and embodiments. It can be understood that the specific embodiments described here are only used to explain the present disclosure, but not to limit the present disclosure. In addition, it should be noted that, for convenience of description, only some but not all structures related to the present disclosure are shown in the drawings, and the shapes and sizes of the elements in the drawings do not reflect their true proportions and are only intended to illustrate the present disclosure.

It will be apparent to those skilled in the art that various modifications and variations can be made in the present application without departing from the spirit or scope of the present application. Thus, the present application is intended to cover modifications and variations of the present application that fall within the scope of the corresponding claims (the technical solutions claimed) and their equivalents. It should be noted that the implementation modes provided in the embodiments of the present application can be combined with each other if there is no contradiction.

An embodiment of the present disclosure provides a semiconductor device, including an active area and a non-active area surrounding the active area. The semiconductor device further includes a substrate, a multilayer semiconductor layer, a plurality of sources, a plurality of gates and a plurality of drains, wherein the multilayer semiconductor layer is located on one side of the substrate, the plurality of sources, the plurality of gates and the plurality of drains are located on one side of the multilayer semiconductor layer away from the substrate and located in the active area, in the active area, the sources, the gates and the drains are alternately arranged along a first direction, and along the first direction, the sources includes two sources respectively closest to ends of the arrangement, and any one of the gates is located between one of the sources and one of the drains, and the first direction is parallel to a plane where the substrate is located, along the first direction, a length of at least a source located at the center along the first direction is greater than lengths of sources located at both ends along the first direction, and the semiconductor device further includes a plurality of rows of through holes extending through the substrate as well as the multilayer semiconductor layer, a plurality of rows of the through holes are arranged along the first direction, and an orthographic projection of the source on the substrate overlaps with an orthographic projection of the through holes on the substrate, along the first direction, the sources located at both ends are correspondingly provided with a rows of the through holes, and at least the source located at the center is correspondingly provided with b rows of the through holes, and b=2*a is satisfied, and both a and b are positive integers, and a≥1, b≥2.

By adopting the above technical solution, both the heat dissipation of the device can be taken into account and the heat dissipation in the center area of the device can be improved, and also the through hole relationship between the ends of the arrangement and the center of the arrangement is set up, so that the current flow path of the central device is similar to that of the edge device, thereby improving the symmetry of the overall current flow path and ensuring the radio frequency characteristics of the semiconductor device.

The above is the core idea of the present application, and based on the embodiments in the present application, all other embodiments obtained by a person of ordinary skill in the art without making creative labor fall within the scope of protection of the present application. The technical solutions in the embodiments of the present application will be clearly and completely described below in conjunction with the drawings in the embodiments of the present application.

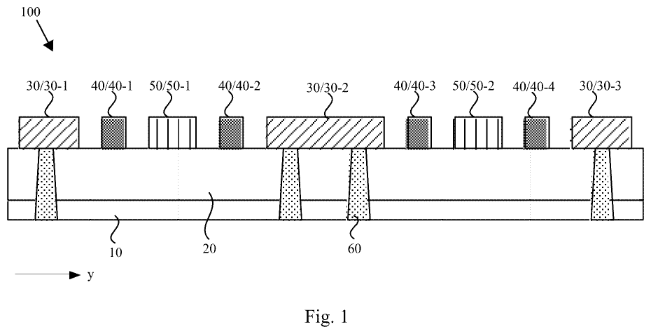

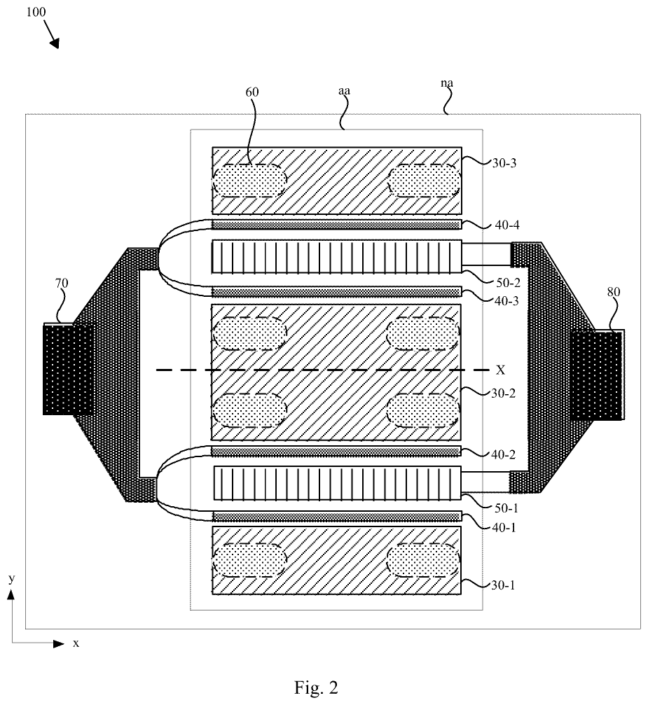

FIG. 1 is a cross-sectional structural schematic diagram of a semiconductor device provided by an embodiment of the present disclosure, and FIG. 2 is a top structural schematic diagram of a semiconductor device provided by an embodiment of the present disclosure. By referring to FIGS. 1 and 2, the semiconductor device 100 provided by an embodiment of the present disclosure includes an active area aa and a non-active area na surrounding the active area aa. The semiconductor device 100 further includes a substrate 10, a multilayer semiconductor layer 20, a plurality of sources 30 (the numbers following 30 are for identification purposes only in the figures), a plurality of gates 40 (the numbers following 40 are for identification purposes only in the figures), and a plurality of drains 50 (the numbers following 50 are for identification purposes only in the figures), wherein the multilayer semiconductor layer 20 is located on one side of the substrate 10. The plurality of sources 30, the plurality of gates 40, and the plurality of drains 50 are located on one side of the multilayer semiconductor layer 20 away from the substrate 10 and located in the active area aa, in the active area aa, the sources 30, the gates 40, and the drains 50 are alternately arranged along a first direction y, and along the first direction y, the sources includes two sources respectively closest to ends of the arrangement, and any one of the gates 40 is located between one of the sources 30 and one of the drains 50, and the first direction y is parallel to a plane where the substrate 10 is located, along the first direction y, a length of at least a source (such as the source 30-2) located at the center along the first direction y is greater than lengths of sources (such as the source 30-1 and the source 30-3) located at both ends along the first direction y, and the semiconductor device 100 further includes a plurality of rows of through holes 60 extending through the substrate 10 as well as the multilayer semiconductor layer 20, a plurality of rows of the through holes 60 are arranged along the first direction y, and an orthographic projection of the source 30 on the substrate 10 overlaps with an orthographic projection of the through holes 60 on the substrate 10, along the first direction y, the sources (such as the source 30-1 and the source 30-3) located at both ends are correspondingly provided with a rows of the through holes 60, and at least the source (such as the source 30-2) located at the center is correspondingly provided with b rows of the through holes 60, and b=2*a is satisfied, and both a and b are positive integers, and a≥1, b≥2. FIG. 2 is illustrated with an example where a=1 and b=2. Additionally, for the purpose of presentation, subsequent drawings are also illustrated with the example where a=1 and b=2.

The semiconductor device provided by the embodiment of the present disclosure is designed as a multi-gate structure. As shown in FIGS. 1 and 2, in the active area aa, the sources 30, the gates 40, and the drains 50 are alternately arranged along the first direction y, and, along the first direction y, any gate 40 is located between a source 30 and a drain 50, and a source 30 or a drain 50 is included between any two adjacent gates 40. Exemplarily, along the first direction, the arrangement order of the source 30, the gate 40, and the drain 50 may be the source 30, the gate 40, the drain 50, the gate 40, the source 30 . . . the source 30, or it may also be the drain 50, the gate 40, the source 30, the gate 40, the drain 50 . . . the drain 50. FIG. 1 takes the first arrangement as an example; at this time, the two electrodes located at the ends of the arrangement are the sources 30; as for the second arrangement, the two electrodes located at the ends of the arrangement are the drains 50.

In addition, as shown in FIG. 2, the semiconductor device 100 further includes a gate bonding pad 70, a drain bonding pad 80, and a plurality of rows of through holes 60, the gate bonding pad 70 is located in the non-active area na on the side of the multilayer semiconductor layer 20 away from the substrate 10, the plurality of gates 40 are all electrically connected to the gate bonding pad 70, the drain bonding pad 80 is located in the non-active area na on the side of the multilayer semiconductor layer 20 away from the substrate 10, and the plurality of drains 50 are all electrically connected to the drain bonding pad 80, the through hole 60 penetrates the substrate 10 and the multilayer semiconductor layer 20, and the orthographic projection of the source 30 on the substrate 10 overlaps with the orthographic projection of the through hole 60 on the substrate 10, in this way, the source 30 may be grounded through the through hole 60. As shown in FIG. 2, generally, the plurality of gates 40 have the same length along the second direction x, the plurality of sources 30 have the same length along the second direction x, and the plurality of drains 50 have the same length along the second direction x, wherein, the second direction x intersects the first direction y and is parallel to the plane where the substrate 10 is located.

It should be noted that each row of through holes only needs to include at least one through hole 60, and the embodiment of the present disclosure does not limit the number of through holes in a row of through holes. In addition, FIG. 2 is illustrated only with an example where the orthographic projection of the source 30 on the substrate 10 covers the orthographic projection of the corresponding through hole 60 on the substrate 10. This structure is not limiting, as long as it is ensured that the orthographic projections of the source 30 and its corresponding through hole 60 on the substrate 10 overlap. Exemplarily, in other embodiments, the orthographic projection of the through hole 60 close to the edge of the source 30 along the second direction x on the source may exceed the edge of the source.

Typically, the gate 40 is negatively biased, the drain 50 is forward biased, and the source 30 is at zero potential (grounded). Referring to FIG. 2, when the semiconductor device is operating, the current flows from any drain 50 through the gates 40 on both sides of the drain 50 to the sources 30 on both sides of the drain 50, and then is connected to the ground through the through hole 60. For example, the current flows from the drain 50-1 to the source 30-1 through the gate 40-1, and flows to the source 30-2 through the gate 40-2, at the same time, the current flows from the drain 50-2 to the source 30-2 through the gate 40-3, and to the source 30-3 through the gate 40-4. When the semiconductor device is operating, the area near the bottom of the gate 40 is the main area where the device generates heat. When the length of the gate 40 along the second direction x is constant, the heat dissipation of the device is mainly limited by the spacing between adjacent gates 40 along the first direction y. It can be understood that the smaller the spacing between the gates 40 is, the slower the heat dissipation will be.

In this embodiment, the source 30 is used as a heat dissipation area, by arranging the length of at least the source located at the center (such as the source 30-2) along the first direction y to be greater than the length of the sources located at both ends (such as the source 30-1 and the source 30-3) along the first direction y, the spacing between the gates (such as the gate 40-2 and the gate 40-3) in the center of the device may be increased, the area of the heat dissipation area in the center of the device may be increased, and the heat dissipation capability of the center area of the device may be improved.

In this embodiment, the plurality of sources 30, the plurality of gates 40, and the plurality of drains 50 are arranged along the first direction y, where, the “source located at the center” can be understood as the source closest to the center of the arrangement among the plurality of sources, and the “sources at both ends” mean the two sources closest to the ends of the arrangement. As mentioned above, the electrodes at the ends of the arrangement may be the sources, at this time, the sources located at both ends are the two sources located at the ends of the arrangement, and the following descriptions will take the electrodes located at the ends of the arrangement as sources as examples. Referring to FIG. 2, in a specific implementation, a plurality of sources 30, a plurality of gates 40, and a plurality of drains 50 may be uniformly and symmetrically distributed along the first direction y in the active area aa, and the center point of the electrode (such as the source 30-2) located at the center of the arrangement among the plurality of electrodes (i.e., the source 30, the gate 40, and the drain 50) passes through the central axis X of the active area aa, at this time, the “source located at the center” can be understood as the source closest to the central axis X of the active area aa, where the central axis X is perpendicular to the first direction y and passes through the midpoint of the active area aa along the first direction y. Exemplarily, in the semiconductor device shown in FIG. 2, three sources are provided in the active area aa, namely source 30-1, source 30-2, and source 30-3, wherein the source 30-1 and the source 30-3 are located at both ends of the active area aa, the source 30-2 is located at the center of the active area aa, and the length of the source 30-2 along the first direction y is greater than the lengths of the source 30-1 and the source 30-3 along the first direction y, which increases the area of the heat dissipation area of the center of the device and improves the heat dissipation capacity of the center area of the device.

Furthermore, in the prior art, the number of rows of through holes in the arrangement center and arrangement edge areas is generally the same. When the length of the source at the center along the first direction y increases, if the source is still provided with the same number of rows of through holes, on the one hand, this will cause the length of the current flow path (the length from the drain to the through hole) to increase, thereby increasing the source resistance and affecting the radio frequency characteristics of the semiconductor device, for example, this may reduce key electrical properties such as the maximum oscillation frequency of the device; on the other hand, this will also cause the current flow path lengths from the same drain to the sources on both sides to be unequal, resulting in asymmetry in the current flow path, and this will also have a greater impact on the radio frequency characteristics of the semiconductor device.

In order to solve the heat dissipation problem in the center area of the device and reduce the impact on the radio frequency characteristics of the device, in this embodiment, while increasing the length of the source 30 at the center along the first direction y, the number b of rows of through hole corresponding to the source 30 at the center is designed to be twice the number a of rows of through hole corresponding to the sources 30 at both ends, by arranging the relationship between the through holes at the end of the arrangement and the center of the arrangement, the current flow path of the central device is similar to the current flow path of the edge device, shortening the length of the current flow path, improving the symmetry of the overall current flow path and ensuring that the device has good radio frequency characteristics.

Exemplarily, referring to FIG. 2, the length of the source 30-2 located at the center along the first direction y increases, at the same time, the source 30-2 is correspondingly provided with two rows of through holes 60, and the source 30-1, and the source 30-2 located at both ends are correspondingly provided with a row of through holes 60. In this way, the current flow path from the drain 50-1 to the source 30-2 is the distance from the drain 50-1 to the through hole 60 closest to the drain 50-1 in the source 30-2, so that the current flow path may be shortened, at the same time, this may improve the symmetry of the current flow paths from the drain 50-1 to the source 30-1, and the source 30-2, in the same way, the current flow path from the drain 50-2 to the source 30-2, and the source 30-3 also has high symmetry, which can ensure that the semiconductor device has good radio frequency characteristics.

It should be noted that FIG. 2 is illustrated only with an example where three sources are set in the active area aa, it can be understood that the number of sources can be greater than 3, at this time, except for the sources located at both ends and the source located at the center, the remaining sources may choose whether to increase the length of the sources along the first direction y according to the heat dissipation requirements, and whether b rows of through holes need to be set can be determined based on the length of the source along the first direction y, which is not limited in the embodiment of the present disclosure, and is only explained here by taking increasing the length of the source located at the center along the first direction y and providing b rows of through holes on the source as an example. In other embodiments, the source located at the center may have the longest length along the first direction y, and the sources closer to both ends may have shorter lengths along the first direction y, which therefore may can improve the heat dissipation capacity of the central area of the device while saving part of the area of the active area aa, so that the active area aa maintains a high area utilization rate.

In addition, each source 30 may be provided with at most two rows of through holes 60 correspondingly, in this way, the current flow path may be shortened, the symmetry of the current flow path may be improved, and the radio frequency characteristics of the semiconductor device may be ensured, and at the same time, excessive through holes may be avoided to affect the heat dissipation capability of the device.

Each row of through holes may include at least one through hole 60, the number of through holes in each row of through holes is equal. FIG. 2 is illustrated only with an example where each row of through holes includes two through holes 60. Further, in each row of the through holes, a line connecting the geometric centers of the through holes at the same number of position may be parallel to the first direction y. Exemplarily, referring to FIG. 2, along the second direction x, the line connecting the geometric center of the first through hole in each row of through holes is parallel to the first direction y, and the line connecting the geometric center of the second through hole in each row of through holes is parallel to the first direction y. In this way, the semiconductor device may have a high degree of symmetry, thereby ensuring that the semiconductor device has good radio frequency characteristics. The substrate 10 may be one or a combination of more of gallium nitride, aluminum gallium nitride, indium gallium nitride, aluminum indium gallium nitride, indium phosphide, gallium arsenide, silicon carbide, diamond, sapphire, germanium, and silicon, or any other material capable of growing Group III nitrides.

The multilayer semiconductor layer 20 may include a semiconductor material based on a Group III-V compound. Specifically, the multilayer semiconductor layer 20 may include a nucleation layer, a buffer layer, a channel layer, and a barrier layer in order from the direction of the substrate 10, wherein, the channel layer and the upper barrier layer together form a heterojunction structure, and the channel layer provides a channel for two-dimensional electron gas movement. The nucleation layer affects parameters such as crystal quality, surface morphology, and electrical properties of the upper heterojunction material. The nucleation layer changes with different substrate 10 materials, and mainly plays a role in matching the substrate 10 material and the semiconductor material layer in the heterojunction structure. The buffer layer plays a role in bonding the semiconductor material layer that needs to be grown next, and may further protect the substrate 10 material from being invaded by some metal ions. The material of the buffer layer may be a Group III nitride material such as AlGaN, GaN, or AlGaInN. In the present disclosure, the buffer layer is a gallium nitride layer (Al)GaN with controllable aluminum content.

In the embodiment of the present disclosure, by arranging the length of at least the source located at the center along the first direction to be greater than the length of the sources located at both ends along the first direction, the area of the source located at the center is greater than the area of the sources located at both ends, which thus increases the area of the heat dissipation area in the central area of the semiconductor device and improves the heat dissipation capacity of the central area of the semiconductor device, at the same time, by arranging the number of rows of through holes corresponding to at least the source located at the center as twice the number of rows of through holes corresponding to the sources located at both ends, while the length of the central source along the first direction is increased, the distance between the through holes thereof and the adjacent gates may be kept short, which thus ensures a short current flow path and ensures the radio frequency characteristics of the semiconductor device.

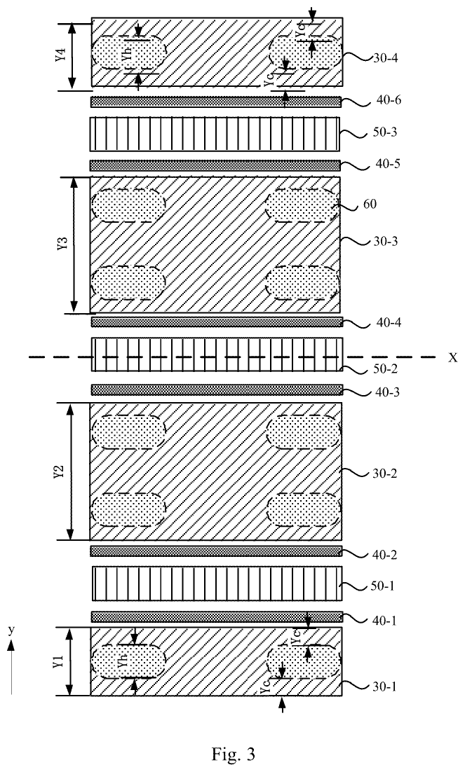

Based on the above embodiments, the number of the sources 30, the gates 40, and the drains 50 in the active area aa may be set according to actual needs. According to the arrangement pattern of the sources 30, the gates 40, and the drains 50, along the first direction, the electrode located at the center of the arrangement may be a source 30 or a drain 50. As shown in FIG. 2, when the electrode located at the center of the arrangement is a source (such as source 30-2) along the first direction y, at least the length of the source (30-2) along the first direction y may be greater than the length of the sources located at both ends along the first direction y, and b rows of through holes 60 are provided correspondingly. FIG. 3 is a partial top structural schematic diagram of a semiconductor device provided by an embodiment of the present disclosure, showing only the structure in the active area aa. Referring to FIG. 3, when the electrode located at the center of the arrangement is a drain along the first direction y, at least the lengths of the two sources closest to the drain along the first direction y are greater than the lengths of the sources located at both ends along the first direction y, and b rows of through holes 60 are provided correspondingly. Exemplarily, in FIG. 3, the source 30-2 and the source 30-3 are closest to the drain 50-2 at the center of the arrangement, lengths of the source 30-2 and the source 30-3 along the first direction y are greater than the lengths of the source 30-1 and the source 30-4 along the first direction y, and b rows of through holes 60 are provided correspondingly.

Further, referring to FIG. 3, along the first direction y, starting from the first source (such as source 30-1) located at either end, the m-th source may be correspondingly provided with b rows of through holes 60. At this time, as long as the length Yₘ of the m-th source along the first direction y satisfies Yₘ≥3Yₕ+2Y_{c}, the source is provided with b rows of through holes correspondingly, and the other sources are provided with a rows of through holes. Generally, in order to ensure excellent radio frequency characteristics, the number of through holes on both sides of the central axis X is the same from the sources at the two arrangement ends to the center, wherein, Yₕ is a length of the through hole 60 along the first direction y, and Y_{c} is a distance between the opposite edges of the sources 30 and the through hole 60 located at both ends in the first direction y, and m is a positive integer greater than 1. By arranging the source length requirements corresponding to b rows of through holes, it is ensured that the through holes on each source of the entire device are kept at a short distance from the adjacent gate, thereby ensuring that all current flow paths of the entire device are short.

Specifically, the length of each source 30 along the first direction y may be adaptively designed according to the heat dissipation requirements of the area where it is located. When the length of the m-th source along the first direction y Yₘ≥3Yₕ+2Y_{c}, the source is provided with b rows of through holes 60 correspondingly, while the remaining sources, that is, when Yₘ<3Yₕ+2Y_{c}, are provided with a rows of through holes. Generally, the sources on both sides of the central axis X are arranged symmetrically with respect to the central axis X, and the length of each source along the first direction y is also symmetrical with respect to the central axis X, then the through holes on both sides of the central axis X are arranged symmetrically with respect to the central axis X, to ensure that the distance between the through hole on each source of the entire device and the adjacent gate is kept as short as possible, and the current flow path of each device is as similar as possible, which thus ensures that all current flow paths of the entire device are short, and avoids affecting the radio frequency characteristics of the semiconductor device when the size of the source along the first direction y is large.

Exemplarily, the second source 30-2 and the third source 30-3 in FIG. 3 are provided with two rows of through holes 60, and the lengths Y2 and Y3 of the two in the first direction y need to meet the above requirements, that is, they need to satisfy Y₂≥3Yₕ+2Y_{c} and Y₃≥3Yₕ+2Y_{c}. However, in FIG. 3, the first source 30-2 and the fourth source 30-3, since the lengths of the two in the first direction y are less than 3Yₕ+2Y_{c}, are provided with a row of through holes.

Therein, Y_{c} is a distance between the opposite edges of the sources 30 and the through hole 60 located at both ends in the first direction y. Referring to FIG. 3, the source 30-1 (or the source 30-4) and the through hole 60 thereof have two sets of opposite edges. Specifically, the upper edge of the source 30-1 is opposite to the upper edge of the through hole 60, and the distance between them in the first direction y is Y_{c}, and the lower edge of the source 30-1 is opposite to the lower edge of the through hole 60, and the distance between them in the first direction y is Y_{c}. Without considering heat dissipation requirements, in order to save area, the length of the source 30 along the first direction y is usually as small as possible while meeting performance and production requirements. As for the sources at both ends (such as source 30-1 and source 30-4 in FIG. 3), their heat dissipation requirements are minimal. Therefore, Y_{c} may be the minimum allowable distance between the opposite edges of the sources 30 and the through hole 60 located at both ends. The length Yₕ of the through hole 60 along the first direction y may be set according to actual requirements, and is not particularly limited in this embodiment of the present disclosure.

Furthermore, in addition to the heat dissipation requirements of the corresponding area, as for the length of the source 30 along the first direction y, it also needs to comprehensively consider the radio frequency characteristics of the semiconductor device and the requirements of the production process.

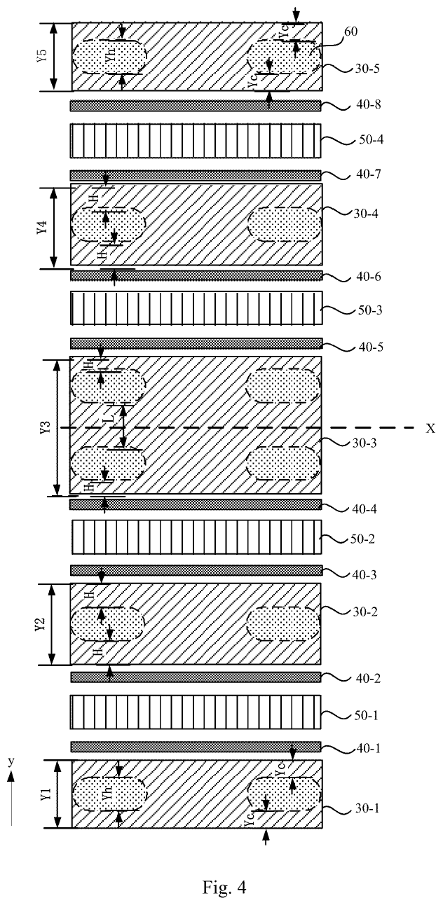

FIG. 4 is a partial top structural schematic diagram of another semiconductor device provided by an embodiment of the present disclosure, and also only shows the structure in the active area aa. Referring to FIG. 4, in order to meet process requirements, the distance L in the first direction y between two rows of through holes 60 corresponding to the same source (such as the source 30-3) may satisfy L≥Yₕ, wherein Yₕ is the length of the through hole 60 along the first direction y. That is, when the source 30 is provided with b rows of through holes 60 correspondingly, in order to meet the process requirements, it is necessary to ensure that the distance between the two rows of through holes 60 in the first direction y is greater than or equal to the length of the through holes 60 along the first direction y.

Continuing referring to FIG. 4, the distance H between the opposite edges of the source 30 and the through hole 60 of the sources 30 in the first direction y located at both ends may satisfy Y_{c}≤H≤Yₕ+Y_{c}, wherein Yₕ is the length of the through hole 60 along the first direction y, and Y_{c} is the distance between the opposite edges of the sources 30 and the through hole 60 located at both ends in the first direction y. Referring to FIG. 4, it can be understood that when the source is provided with b rows of through hole 60 (such as the source 30-3) correspondingly, the distance between the opposite edges of the source 30 and the through hole 60 in the first direction y specifically refers to the distance between an edge of the source 30 and an edge of the through hole 60 closest to the former edge.

Specifically, according to the above explanation, it can be known that the distance between the opposite edges of the source 30 and the through hole 60 in the first direction y determines the length of the current flow path. Therefore, the distance between the opposite edges of the source 30 and the through hole 60 in the first direction y should not be too large, and may be Y_{c}≤H≤Yₕ+Y_{c}, the through holes are correspondingly set at the source, but they are not set arbitrarily, and it is necessary to ensure that the edge distances between all sources and through holes of the entire device satisfy Y_{c}≤H≤Yₕ+Y_{c} to ensure that the semiconductor device has good radio frequency characteristics. In addition, when the source is provided with b rows of through holes, it may be that H=Y_{c}, to make the distance between the edges of the through hole at the center of the arrangement and the opposite source the same as the distance between the through hole at the edge of the arrangement and the edge of the opposite source, to reduce the current flow path, ensure that the current path in the center is the same as the current path at the edge, and improve the radio frequency characteristics of the device.

In summary, taking the structure (a=1, b=2) shown in FIG. 4 as an example, the technical solution of the embodiments of the present disclosure shall be generally illustrated. In FIG. 4, the first source 30-1 is located at one end of the active area aa, and its length Y₁ along the first direction y is the smallest. Along the first direction y, the second source 30-2 is closer to the center of the device than the first source 30-1, so its length Y₂ in the first direction y may be appropriately increased (Y₂>Y₁). At the same time, when the length of Y₂ does not meet the requirements for designing two rows of through holes 60 (does not satisfy Y₂≥3Yₕ+2Y_{c}), it should be ensured that the distance H between the opposite edges of the source 30-2 and the through hole 60 is less than or equal to (Yₕ+Y_{c}) and greater than or equal to Y_{c}, to increase the heat dissipation capacity of this area to a certain extent, and at the same time avoid excessively increasing the length of the current flow path from the drain 50-1 to the source 30-2, and reduce the impact on the radio frequency performance of the device. Continuing along the first direction y, the third source 30-3 is located at the center of the electrode arrangement, which allows its length Y₃ along the first direction y to satisfy Y₃≥3Yₕ+2Y_{c}, thereby increasing the area of the source 30-3 and improving the heat dissipation capability of the centra area. At the same time, since the length of the source 30-3 along the first direction y meets the requirement of providing two rows of through holes 60, it is possible to avoid the situation that only one row of through holes 60 can be provided due to the long length of the source 30-3, and avoid affecting the radio frequency performance of the semiconductor device by increasing the length of the current flow path. In addition, since the source 30-3 is provided with two rows of through holes 60 correspondingly, it may be that the distance L between the two rows of through holes 60 is greater than or equal to the length Yₕ of the through holes 60 along the first direction y. Furthermore, as for the source 30-3, it is also may be that the distance H between the opposite edges of the source 30-3 and the through hole 60 in the first direction y is less than or equal to (Yₕ+Y_{c}) and greater than or equal to Y_{c} (may be H=Y_{c}), to avoid excessively increasing the length of the current flow path from the drain 50-2 and the drain 50-3 to the source 30-3, and reduce the impact on the radio frequency performance of the device. The source 30-4 can be designed to be symmetrical with the source 30-2, and the source 30-5 can be designed to be symmetrical with the source 30-1. No further explanation will be given here.

Finally, in combination with FIGS. 2-4, it should be noted that in the present application, the number of through-hole rows corresponding to each source is a or b, to ensure the approximation and symmetry of all current flow paths in the semiconductor device and improve the stability of the semiconductor device. Furthermore, among any two of the nearest sources, number of rows of through holes corresponding to the source close to the center of the arrangement is greater than or equal to number of rows of through holes corresponding to the sources away from the center of the arrangement. Taking FIG. 4 as an example, the source 30-2 and the source 30-1 are close to each other, wherein the source 30-2 is closer to the center of the arrangement than the source 30-1, the source 30-2 is correspondingly provided with a row of through holes, and the source 30-1 is correspondingly provided with a row of through holes. The source 30-3 and the source 30-3 are close to each other, wherein the source 30-3 is closer to the center of the arrangement than the source 30-2, the source electrode 30-3 is correspondingly provided with two rows of through holes, and the source electrode 30-2 is correspondingly provided with a row of through holes.

It should be understood that the embodiments of the present disclosure improve the performance of the semiconductor device from the perspective of structural design of the semiconductor device. The semiconductor devices include but are not limited to high-power gallium nitride High Electron Mobility Transistors (HEMT) operating under high voltage and high current environments, Transistors with a Silicon-On-Insulator (SOI) structure on an insulating substrate, Gallium Arsenide (GaAs)-based transistors and Metal-Oxide-Semiconductor Field-Effect Transistors (MOSFETs), metal-insulating layer semiconductor field-effect transistors (Metal-Semiconductor Field-Effect Transistor, or MISFET), Double Heterojunction Field-Effect Transistors (DHFET), Junction Field-Effect Transistors (JFET), Metal-Semiconductor Field-Effect Transistors (MESFET), metal-insulating layer semiconductor Heterojunction Field-Effect Transistors (Metal-Semiconductor Heterojunction Field-Effect Transistor, or MISHFET) or other field-effect transistors.

It should be noted that the above are only the example embodiments of the present disclosure and the technical principles used. Those skilled in the art will understand that the present disclosure is not limited to the specific embodiments described herein. Various obvious changes, readjustments and substitutions can be made by those skilled in the art without departing from the scope of the present disclosure. Therefore, although the present disclosure has been described in detail through the above embodiments, the present disclosure is not limited to the above embodiments. Without departing from the concept of the present disclosure, the present disclosure may also include more other equivalent embodiments, and the scope of the present disclosure is determined by the scope of the appended claims.

1. A semiconductor device comprising an active area and a non-active area surrounding the active area, the semiconductor device further comprising:
a substrate;
a multilayer semiconductor layer located on one side of the substrate; and
a plurality of sources, a plurality of gates, and a plurality of drains located on one side of the multilayer semiconductor layer opposite the substrate and located in the active area, wherein, in the active area, the sources, the gates, and the drains are alternately arranged along a first direction, wherein along the first direction, the sources comprise two sources respectively closest to ends of the arrangement, wherein any one of the gates is located between one of the sources and one of the drains, and wherein the first direction is parallel to a plane where the substrate is located;
wherein, along the first direction, a length of at least a source located at a center along the first direction is greater than lengths of sources located at both ends along the first direction; and
wherein the semiconductor device further comprises a plurality of rows of through holes extending through the substrate as well as the multilayer semiconductor layer, wherein a plurality of rows of the through holes are arranged along the first direction, wherein an orthographic projection of the source on the substrate overlaps with an orthographic projection of the through holes on the substrate, wherein along the first direction, the sources located at both ends are correspondingly provided with rows of the through holes, wherein at least the source located at the center is correspondingly provided with b rows of the through holes, wherein b=2*a is satisfied, wherein both a and b are positive integers, wherein a≥1, and wherein b≥2.

2. The semiconductor device according to claim 1, wherein, along the first direction, an electrode located at the center of the arrangement is a drain; and
wherein lengths of at least the two sources closest to the drain along the first direction are greater than lengths of the sources located at both ends along the first direction, and wherein the b rows of the through holes are provided correspondingly.

3. The semiconductor device according to claim 1, wherein, along the first direction, the electrode located at the center of the arrangement is a source; and
wherein a length of at least the source along the first direction is greater than lengths of the sources located at both ends along the first direction, and wherein the b rows of the through holes are provided correspondingly.

4. The semiconductor device according to claim 1, wherein a number of rows of the through holes provided corresponding to each source is one of a and b.

5. The semiconductor device according to claim 4, wherein, among any two of the nearest sources, the number of rows of the through holes corresponding to the source close to the center of the arrangement is greater than or equal to the number of rows of the through holes corresponding to the sources opposite the center of the arrangement.

6. The semiconductor device according to claim 1, wherein, along the first direction, starting from a first source located at one end, a m-th source is provided with the b rows of the through holes correspondingly;
wherein a length Yₘ of the m-th source along the first direction satisfies Yₘ≥3Yₕ+2Y_{c}; and
wherein Yₕ is a length of the through hole along the first direction, wherein Y_{c} is a distance between the opposite edges of the sources and the through hole located at both ends in the first direction, and wherein m is a positive integer greater than 1.

7. The semiconductor device according to claim 1, wherein a distance L between two rows of the through holes corresponding to the same source in the first direction satisfies L≥Yₕ; and
wherein Yₕ is a length of the through hole along the first direction.

8. The semiconductor device according to claim 1, wherein a distance H between the opposite edges of the sources and the through holes between the sources located at both ends in the first direction satisfies Y_{c}≤H≤Yₕ+Y_{c}; and
wherein Yₕ is a length of the through hole in the first direction, and wherein Y_{c} is a distance between the opposite edges of the sources and the through holes located at both ends in the first direction.

9. The semiconductor device according to claim 1, wherein the number of the through holes in each row of the through holes is equal.

10. The semiconductor device according to claim 8, wherein, in each row of the through holes, a line connecting the geometric centers of the through holes at the same number of position is parallel to the first direction.
